(19) United States
(12) Patent Application Publication
(10) Pub. No.: US 2015/0214464 A1
(43) Pub. Date: Jul. 30, 2015

(54) VIBRATION GENERATING DEVICE

(71) Applicant: SAMSUNG ELECTRO-MECHANICS CO., LTD., Suwon-Si (KR)

(72) Inventors: Yun Yeong PARK, Suwon-Si (KR); Yeun Ho JUNG, Suwon-Si (KR); Byung Hoon LEE, Suwon-Si (KR); Dong Woo RHEE, Suwon-Si (KR)

(73) Assignee: SAMSUNG ELECTRO-MECHANICS CO., LTD., Suwon-Si (KR)

(21) Appl. No.: 14/590,976

(22) Filed: Jan. 6, 2015

(30) Foreign Application Priority Data
Jan. 28, 2014 (KR) 10-2014-0010058

(51) Int. Cl. H01L 41/053; H01L 41/09

(52) U.S. Cl. CPC H01L 41/0533; H01L 41/09

(57) ABSTRACT

There is provided a vibration generating device including: a housing having an internal space; a vibrating member of which both end portions are fixed to the housing; a piezoelectric element fixed to a top surface of the vibrating member; a mass body disposed on the piezoelectric element; and a coupling member connecting the mass body and the vibrating member to each other and including a hook portion connected to the vibrating member by elastic deformation.

### CROSS-REFERENCE TO RELATED APPLICATION

This application claims the priority and benefit of Korean Patent Application No. 10-2014-0010058 filed on Jan. 28, 2014, with the Korean Intellectual Property Office, the disclosure of which is incorporated herein by reference.

### BACKGROUND

The present disclosure relates to a vibration generating device.

A vibration generating device, a device converting electrical energy into mechanical vibrations using the principle of the generation of electromagnetic force, is mounted in a mobile phone, or the like, to thereby be used for silently notifying a user of call reception by transferring vibrations to the user.

In addition, the market for mobile devices such as mobile phones is rapidly expanded. Further, there is a trend for greater amounts of functionality to be added to mobile devices. In addition, in line with market demand, mobile devices are required to have high levels of quality while being relatively small sized.

In accordance with the above-mentioned trend, demand for the development of vibration generating devices having novel structures capable of overcoming disadvantages of existing vibration generating devices and significantly improving the quality thereof has increased.

Further, mobile phones have recently been supplanted by smartphones in many markets, and touchscreen user interfaces have commonly been adopted in smartphones. Therefore, the use of vibration generating devices for generating vibrations in response to touch interactions with touchscreens of smartphones has increased.

In addition, vibration generating devices using piezoelectric elements have recently been commercialized. Such vibration generating devices, utilizing the principle of an inverse piezoelectric effect generating displacement through the application of a voltage to the piezoelectric element, generate vibratory force by allowing a mass body of an oscillator to be moved by the generated displacement.

Since the vibration generating device having the above-mentioned structure has a broad frequency band allowing vibratory force of a predetermined level or more to be obtained, it may obtain stable vibrating characteristics.

Meanwhile, a piezoelectric element, a mass body, and a vibrating member, constituting an oscillator, are generally assembled using at least one of welding and adhesion. That is, a piezoelectric element, a mass body, and a vibrating member are assembled so as to be integrally moved.

In this case, when external impacts are applied to a mobile device, a load is transferred to the mass body having a relatively heavy weight, and the mass body subsequently contacts the piezoelectric element, and thus, the load transferred to the mass body may be entirely transferred to the piezoelectric element and/or the vibrating member.

Therefore, the piezoelectric element may be easily damaged.

As a result, the development of a structure capable of reducing damage to piezoelectric elements due to external impacts has been urgently demanded.

### RELATED ART DOCUMENT

(Patent Document 1) Korean Patent Laid-Open Publication No. 2011-45486

### SUMMARY

An aspect of the present disclosure may provide a vibration generating device capable of reducing damage to a piezoelectric element due to external impacts.

According to an aspect of the present disclosure, a vibration generating device may include: a housing having an internal space; a vibrating member of which both end portions are fixed to the housing; a piezoelectric element fixed to a top surface of the vibrating member; a mass body disposed on the piezoelectric element; and a coupling member connecting the mass body and the vibrating member to each other and including a hook portion connected to the vibrating member by elastic deformation.

The vibration generating device may further include a buffering member disposed between the piezoelectric element and the mass body.

The vibration generating device may further include an elastic force providing member disposed between the mass body and the coupling member and providing elastic force when the coupling member is coupled.

The mass body may be provided with an installation groove in which the elastic force providing member is disposed to be inserted thereinto.

The coupling member may include a body surrounding the top of the mass body and the hook portion extended from the body.

An end of the hook portion may be provided with a bent portion for preventing separation of the vibrating member.

The vibrating member may be provided with a separation preventing protrusion for preventing separation of the hook portion at the time of installing the coupling member.

The vibration generating device may further include a circuit board connected to a top surface of the piezoelectric element.

The housing may include a case having an internal space and an open bottom, and a bracket provided with a supporting part supporting both end portions of the vibrating member.

### BRIEF DESCRIPTION OF THE DRAWINGS

The above and other aspects, features and advantages of the present disclosure will be more clearly understood from the following detailed description taken in conjunction with the accompanying drawings, in which:

FIG. 1 is a schematic cross-sectional view of a vibration generating device according to an exemplary embodiment in the present disclosure;

FIG. 2 is an exploded perspective view of a vibration generating device according to an exemplary embodiment in the present disclosure;

FIG. 3 is an enlarged view of part A of FIG. 1; and

FIGS. 4 and 5 are views illustrating a method for assembling a coupling member.

### DETAILED DESCRIPTION

Exemplary embodiments of the present disclosure will now be described in detail with reference to the accompanying drawings.

The disclosure may, however, be exemplified in many different forms and should not be construed as being limited to the specific embodiments set forth herein. Rather, these embodiments are provided so that this disclosure will be thorough and complete, and will fully convey the scope of the disclosure to those skilled in the art.

In the drawings, the shapes and dimensions of elements may be exaggerated for clarity, and the same reference numerals will be used throughout to designate the same or like elements.

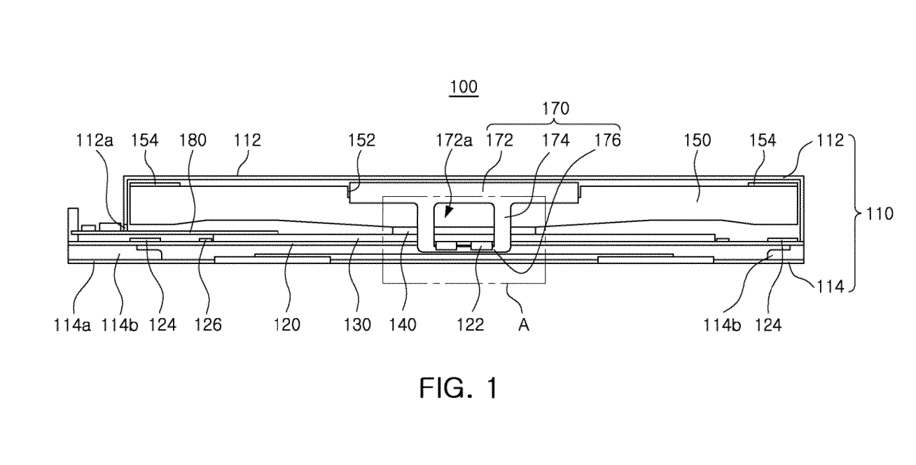

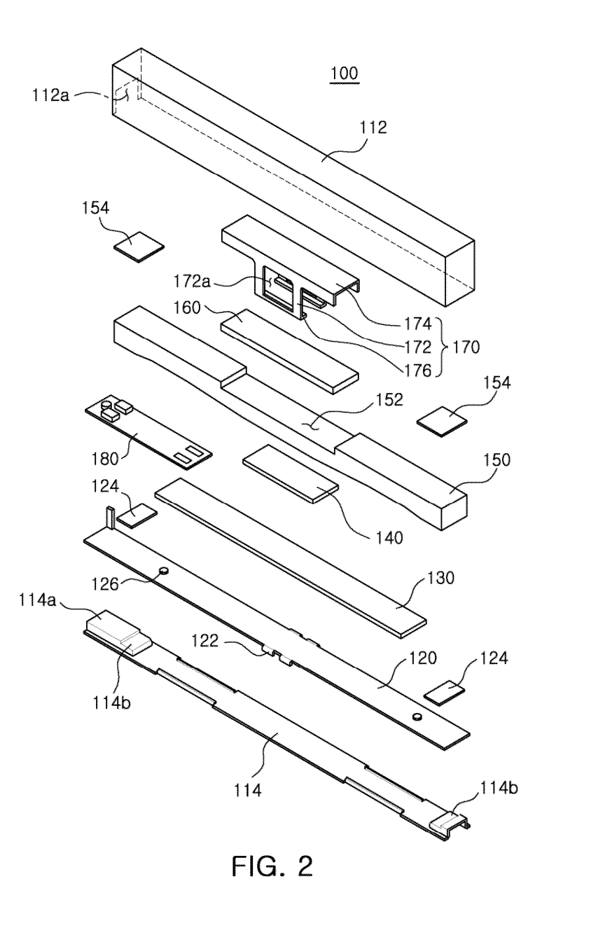

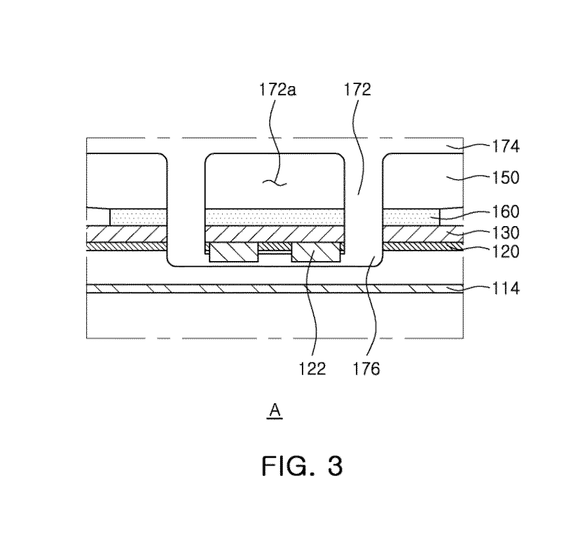

FIG. 1 is a schematic cross-sectional view of a vibration generating device according to an exemplary embodiment in the present disclosure, FIG. 2 is an exploded perspective view of a vibration generating device according to an exemplary embodiment in the present disclosure, and FIG. 3 is an enlarged view illustrating part A of FIG. 1.

Referring to FIGS. 1 through 3, a vibration generating device 100 according to an exemplary embodiment in the present disclosure may include a housing 110, a vibrating member 120, a piezoelectric element 130, a buffering member 140, amass body 150, an elastic force providing member 160, a coupling member 170, and a circuit board 180 by way of example.

The housing 110 may form an exterior appearance of the vibration generating device 100 and may have an internal space so that the vibrating member 120, the piezoelectric element 130, and the mass body 150, and the like may be accommodated therein. To this end, the housing 110 may include a box-shaped case 112 having an internal space and an open bottom, and a bracket 114 which is assembled to the bottom end of the case 112.

Meanwhile, the case 112 may have a hexahedral shape and the bracket 114 may have a plate shape. That is, the bracket 114 may be assembled to the bottom end of the case 112 to form the housing 110.

The housing 110 having the hexahedral shape is exemplified in the present exemplary embodiment, but the shape of the housing is not limited thereto. That is, the housing 110 may be deformed to have various shapes.

In addition, a groove 112a may be formed in one end surface of the case 112 to expose the circuit board 180.

In addition, the bracket 114 may be longer than the case 112, and one exposed end of the circuit board 180 may be seated on the bracket 114. That is, the bracket 114 may be provided with an installing part 114a on which one end of the circuit board 180 exposed out of the housing 110 is seated, and the installing part 114a may be disposed outside the case 112.

Meanwhile, both end portions of the bracket 114 may be provided with supporting parts 114b for installing the vibrating member 120. The supporting parts 114b may be formed by denting. Meanwhile, both end portions of the vibrating member 120 may be bonded to the supporting parts 114b by welding. However, the present inventive concept is not limited thereto, and both end portions of the vibrating member 120 may be installed on the supporting parts 114b by using an adhesive.

Both end portions of the vibrating member 120 may be fixed to the housing 110. That is, as described above, both end portions of the vibrating member 120 may be installed to be bonded to the supporting parts 114b of the bracket 114. Meanwhile, the vibrating member 120 may have the plate shape and both end portions thereof may be fixed to the supporting parts 114b such that the vibrating member 120 is vertically vibrated when the piezoelectric element 130 is deformed.

Meanwhile, both side surfaces of the vibrating member 120 may be provided with separation preventing protrusions 122 for preventing separation of the coupling member 170.

In addition, the separation preventing protrusions 122 may protrude from both side surfaces of the vibrating member 120 and two separation preventing protrusions 122 may be disposed on each side surface of the vibrating member 120 to be spaced apart from each other.

Details thereof will be provided together with a description of the coupling member 170.

In addition, a first damper member 124 may be installed on the top surface of both end portions of the vibrating member 120 so as to reduce noise occurrence due to a contact with the mass body 150 during vibrations. The first damper member 124 may serve to reduce noise and prevent damage to the vibrating member 120 due to the contact with the mass body 150.

Meanwhile, supporting protrusions 126 may be provided on the top surface of the vibrating member 120 to support both end surfaces of the piezoelectric element 130. The supporting protrusions 126 may serve to allow the vibrating member 120 to be more smoothly vibrated when the piezoelectric element 130 is deformed.

Here, the terms, “both side surfaces” of an element refer to longer surfaces thereof and “both end surfaces” of the element refer to shorter surfaces thereof. For example, the housing 110 is formed in a hexahedral shape including a top surface, a bottom surface, both side surfaces having larger areas than those of both end surfaces, and both end surfaces having smaller areas than those of both side surfaces.

The piezoelectric element 130 may be installed on one surface of the vibrating member 120. As an example, the piezoelectric element 130 may be installed on the top surface of the vibrating member 120. In addition, the piezoelectric element 130 may be deformed in a case in which power is supplied thereto, thereby vibrating the vibrating member 120. To this end, the piezoelectric element 130 may be provided with at least one pair of external electrodes (not illustrated), and the external electrodes may include a positive (+) electrode and a negative (−) electrode.

Meanwhile, in the case in which the power is applied to the piezoelectric element 130, the piezoelectric element 130 may be deformed in a length direction, thereby vertically vibrating a central portion of the vibrating member 120.

The buffering member 140 may be disposed between the piezoelectric member 130 and the mass body 150. As an example, the buffering member 140 may be installed on the top surface of the piezoelectric element 130. Meanwhile, the buffering member 140 may be formed of tape having elasticity, and may allow the piezoelectric element 130 and the mass body 150 to be spaced apart from each other by a predetermined distance without direct contact therebetween.

That is, in a case in which external impacts are applied, the buffering member 140 may prevent the piezoelectric element 130 from being damaged by the mass body 150 directly colliding with the piezoelectric element 130. In addition, the buffering member 140 may be shorter than the piezoelectric element 130.

The mass body 150 may be disposed on the piezoelectric element 130 and may be connected to the vibrating member 120 through the coupling member 170. Meanwhile, the mass body 150 may serve to amplify vibrations generated by the deformation of the piezoelectric element 130. To this end, the mass body 150 may be formed of a tungsten material.

Meanwhile, the mass body 150 may be provided with an installation groove 152 in which the elastic force providing member 160 is disposed to be inserted thereinto. That is, the installation groove 152 may be recessed from the top surface of the mass body 150 and serve to allow the elastic force providing member 160 to be inserted thereinto.

In addition, a second damper member 154 may be installed on the top surface of the mass body 150 to prevent noise occurrence and damage when the mass body 150 is in contact with the housing 110 and the vibrating member 120. The second damper member 154 may also be formed of an elastic material similar to that of the first damper member 124. For example, the second damper member 154 may be formed of a material such as rubber or phorone.

The elastic force providing member 160 may be installed in the installation groove 152 of the mass body 150, and may be compressed at the time of installing the coupling member 170 to thereby provide force toward the top of the coupling member 170. To this end, the elastic force providing member 160 may be formed of a material having elasticity and may have a shape corresponding to that of the installation groove 152.

In other words, in a case in which the coupling member 170 is installed, the elastic force providing member 160 may be compressed by the coupling member 170, and consequently, restoring force may be generated from the elastic force providing member 160. Force pushing the coupling member 170 upwardly may be transferred to the coupling member 170 by the restoring force.

Details thereof will be provided below.

The coupling member 170 may connect the mass body 150 and the vibrating member 120 to each other and may include a hook portion 172 connected to the vibrating member 120 by elastic deformation. More specifically, the coupling member 170 may include a body 174 formed to surround the top of the mass body 150, and the hook portion 172 extended from the body 174 downwardly.

Both sides of the body 174 may be bent to thereby provide an internal space into which the top of the mass body 150 is inserted. In addition, the hook portion 172 may be extended from both sides of the body 174 downwardly. Further, a bent portion 176 may be provided at ends of the hook portion 172 to prevent the vibrating member 120 from being separated. In addition, in a case in which the coupling member 170 is installed, the bent portion 176 may support the bottom surface of the vibrating member 120.

In addition, the hook portion 172 may be provided with openings 172a so that the separation preventing protrusions 122 formed on the vibrating member 120 may be fit thereinto.

As described above, the bottom surface of the vibrating member 120 may be supported by the bent portion 176, and the separation preventing protrusions 122 of the vibrating member 120 may be inserted into the openings 172a, while the force compressing the body 174 upwardly is transferred to the coupling member 170 by the elastic force providing member 160 at the same time, and thus the coupling member 170 may more stably connect the mass body 150 and the vibrating member 120 to each other.

In addition, since the piezoelectric element 130 installed on the vibrating member 120 and the mass body 150 connected by the coupling member 170 may independently show separate movements when external impacts are applied thereto, damage to the piezoelectric element 130 by the external impacts may be prevented.

The circuit board 180 may be connected to the piezoelectric element 130 and serve to supply external power to the piezoelectric element 130. Meanwhile, the circuit board 180 may be a flexible circuit board so as to be vibrated together with the vibrating member 120. Meanwhile, one end of the circuit board 180 may be exposed to the outside of the housing 110 through the groove 112a of the case 112, as described above.

Since the mass body 150 is connected to the vibrating member 120 through the coupling member 170, the damage to the piezoelectric element 130 by the mass body 150 at the time of the external impact may be prevented.

Further, since the mass body 150 and the vibrating member 120 is connected to each other through the coupling member 170, the mass body 150 and the vibrating member 120 may be more stably connected to each other.

That is, the bent portion 176 supports the bottom surface of the vibrating member 120 while compressing the bottom of the vibrating member 120 by the restoring force applied by the elastic force providing member 160, such that the mass body 150 and the vibrating member 120 may be more stably connected to each other.

Further, the separation preventing protrusions 122 of the vibrating member 120 are inserted and coupled to the openings 172a of the hook portion 172, such that a separation of the vibrating member 120 and the coupling member 170 in a length direction may be prevented.

Hereinafter, a method for assembling a coupling member included in a vibration generating device according to an exemplary embodiment in the present disclosure will be described with reference to the accompanying drawings.

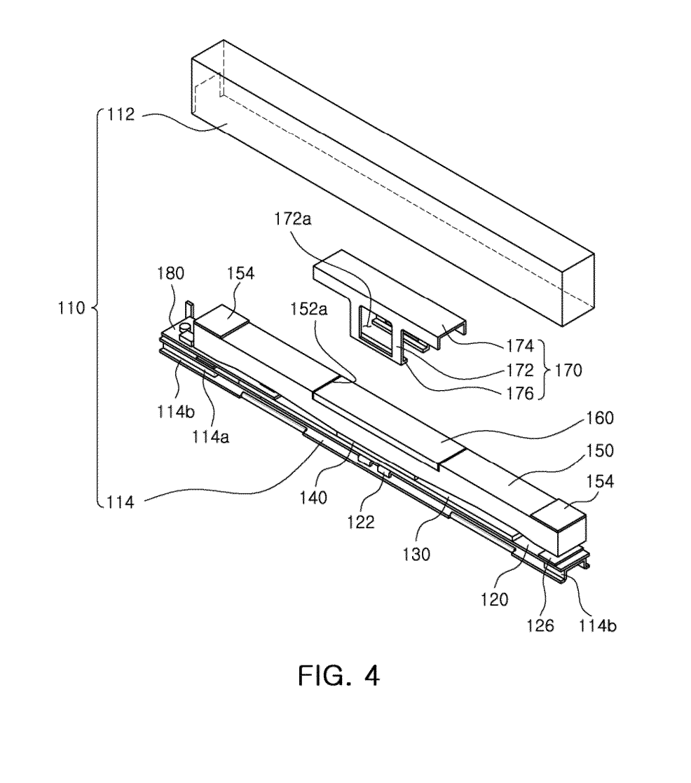

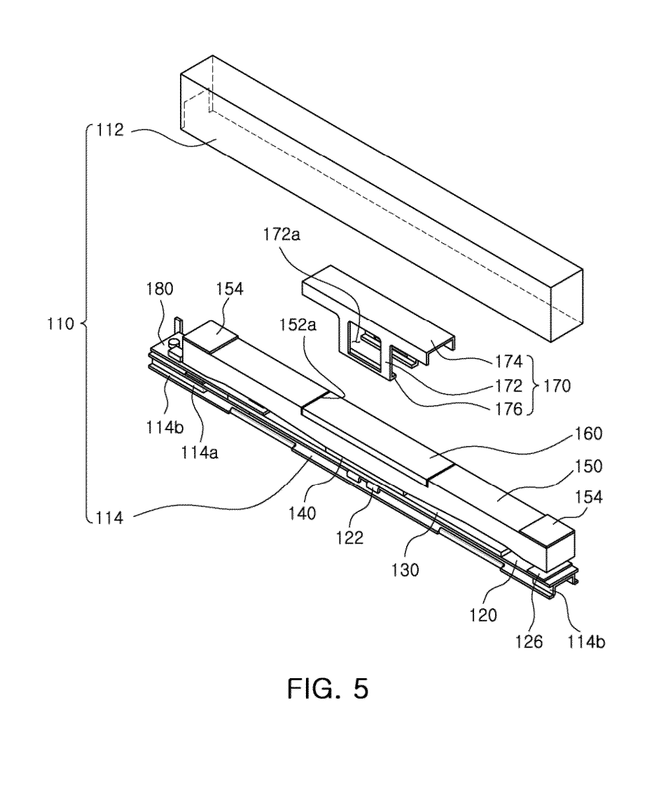

FIGS. 4 and 5 are views illustrating a method for assembling a coupling member.

First, as illustrated in FIG. 4, the mass body 150 may be seated on the buffering member 140 which is installed on the top surface of the piezoelectric element 130. Further, the elastic force providing member 160 may be installed in the installation groove 152 of the mass body 150.

Next, as illustrated in FIG. 4, the coupling member 170 may be prepared.

In addition, as illustrated in FIG. 5, the coupling member 170 may be coupled to the mass body 150 so that the body 174 accommodates the elastic force providing member 160 therein in a state in which the hook portion 172 of the coupling member 170 is elastically deformed.

Thereafter, when the hook portion 172 which is elastically deformed is restored to an original state, the bent portion 176 formed at the ends of the hook portion 172 may support the bottom surface of the vibrating member 120. In addition, the separation preventing protrusions 152 formed on the vibrating member 120 may be disposed to be inserted into the openings 172a formed in the hook portion 172.

In addition, the force may be applied to the top of the coupling member 170 due to the restoring force provided by the elastic force providing member 160 and the bent portion 176 supports the bottom surface of the vibrating member 120, such that the separation of the coupling member 170 may be prevented.

Further, since the separation preventing protrusions 152 may be inserted into the openings 172a of the hook portion 172, the movement of the coupling member 170 in the length direction may be reduced.

As described above, since the mass body 150 and the vibrating member 120 are connected to each other through the coupling member 170, the damage to the piezoelectric element 130 by the mass body 150 may be reduced.

In other words, in a case in which the mass body and the vibrating member are bonded to each other by welding, using an adhesive, or the like, the mass body, the vibrating member, and the piezoelectric element may move together when external impacts are applied thereto, and a load transferred to the mass body may directly be transferred to the piezoelectric element, causing damage to the piezoelectric element.

However, as described above, the mass body 150 and the vibrating member 120 may independently show separate movements by connecting mass body 150 and the vibrating member 120 to each other through the coupling member 170. Further, the piezoelectric element 130 installed on the vibrating member 120 and the mass body 150 may also show separate movements.

As a result, the damage to the piezoelectric element 130 due to the external impacts may be reduced.

Further, since the mass body 150 and the vibrating member 120 are connected to each other through the coupling member 170, the mass body 150 and the vibrating member 120 may be more stably connected to each other.

That is, the bent portion 176 supports the bottom surface of the vibrating member 120 while compressing the bottom surface of the vibrating member 120 by the restoring force provided by the elastic force providing member 160, such that the mass body 150 and the vibrating member 120 may be more stably connected to each other.

Further, the separation preventing protrusions 122 of the vibrating member 120 are inserted and coupled to the openings 172a of the hook portion 172, such that the separation of the vibrating member 120 and the coupling member 170 in the length direction may be prevented.

As set forth above, according to exemplary embodiments, since the mass body is moved separately from the piezoelectric element by assembling the mass body and the vibrating member through the coupling member when external impacts are applied thereto, the damage to the piezoelectric element may be reduced.

While exemplary embodiments have been shown and described above, it will be apparent to those skilled in the art that modifications and variations could be made without departing from the scope of the invention as defined by the appended claims.

What is claimed is:

1. A vibration generating device, comprising:
a housing having an internal space;
a vibrating member of which both end portions are fixed to the housing;
a piezoelectric element fixed to a top surface of the vibrating member;
a mass body disposed on the piezoelectric element; and
a coupling member connecting the mass body and the vibrating member to each other and including a hook portion connected to the vibrating member by elastic deformation.

2. The vibration generating device of claim 1, further comprising a buffering member disposed between the piezoelectric element and the mass body.

3. The vibration generating device of claim 1, further comprising an elastic force providing member disposed between the mass body and the coupling member and providing elastic force when the coupling member is coupled.

4. The vibration generating device of claim 3, wherein the mass body is provided with an installation groove in which the elastic force providing member is disposed to be inserted thereinto.

5. The vibration generating device of claim 4, wherein the coupling member includes:
a body surrounding the top of the mass body; and
the hook portion extended from the body.

6. The vibration generating device of claim 5, wherein an end of the hook portion is provided with a bent portion for preventing separation of the vibrating member.

7. The vibration generating device of claim 1, wherein the vibrating member is provided with a separation preventing protrusion for preventing separation of the hook portion at the time of installing the coupling member.

8. The vibration generating device of claim 1, further comprising a circuit board connected to a top surface of the piezoelectric element.

9. The vibration generating device of claim 1, wherein the housing includes:
a case having an internal space and an open bottom; and
a bracket provided with a supporting part supporting both end portions of the vibrating member.

10. A vibration generating device, comprising:
a housing having an internal space;
a vibrating member of which both end portions are fixed to the housing;
a piezoelectric element fixed to a top surface of the vibrating member;
a mass body disposed on the piezoelectric element;
a coupling member connecting the mass body and the vibrating member to each other and including a hook portion connected to the vibrating member by elastic deformation;
a buffering member disposed between the piezoelectric element and the mass body; and
an elastic force providing member disposed between the mass body and the coupling member and providing elastic force when the coupling member is coupled.

11. The vibration generating device of claim 10, wherein the coupling member includes:
a body surrounding the top of the mass body; and
the hook portion extended from the body.
